(19) United States
(12) Patent Application Publication
(10) Pub. No.: US 2026/0160792 A1
(43) Pub. Date: Jun. 11, 2026

(54) RF SENSOR SYSTEM

(71) Applicant: Samsung Electronics Co., Ltd., Suwon-si (KR)

(72) Inventors: JONGHUN PI, Suwon-si (KR); SEJIN OH, Suwon-si (KR); CHANGSOON LIM, Suwon-si (KR); DOHOON KWON, Suwon-si (KR); KYUNGGON YOU, Suwon-si (KR); SUNGHO JANG, Suwon-si (KR)

(21) Appl. No.: 19/249,352

(22) Filed: Jun. 25, 2025

(30) Foreign Application Priority Data
Dec. 6, 2024 (KR) 10-2024-0180950

(51) Int. Cl. G01R 29/08; H01J 37/32

(52) U.S. Cl. CPC G01R 29/0878; H01J 37/32082; H01J 2237/24564

(57) ABSTRACT

An RF sensor system having first and second modes comprises a housing and an RF sensor coupled to the housing in the first mode. The housing includes a hole including an area where an RF transmission rod is disposed and a sensor coupling area configured for the RF sensor to be coupled.

### CROSS-REFERENCE TO RELATED APPLICATIONS

The application claims benefit of priority under 35 U.S.C. § 119 to Korean Patent Application No. 10-2024-0180950, filed on Dec. 6, 2024, in the Korean Intellectual Property Office, the content of which is incorporated by reference herein in its entirety.

### BACKGROUND

The present disclosure relates generally to an RF sensor system.

Plasma process devices are used for etching, deposition, surface treatment, etc. in the manufacturing processes of semiconductor devices, displays, etc. Plasma process devices generate plasma by ionizing process gas in a vacuum chamber. RF (Radio Frequency) power is used for plasma generation. Measurement of RF voltage and RF current is used to improve the performance and reliability of plasma process equipment.

### SUMMARY

One or more example embodiments provide an RF sensor system with a small change in the characteristic impedance of the RF path when measuring RF characteristics.

One or more example embodiments provide an RF sensor system which reduces resources used for device setup for RF characteristic measurement.

According to an embodiment, an RF sensor system having first and second modes comprises a housing and an RF sensor coupled to the housing in the first mode. The housing includes a hole including an area where an RF transmission rod is disposed and a sensor coupling area configured for the RF sensor to be coupled.

According to an embodiment, an RF sensor system comprises a housing, and an RF sensor coupled to the housing. The housing includes, a hole including an area where an RF transmission rod is disposed, and a slot on the hole. The RF sensor is inserted into the slot and includes a circuit layer including metal patterns and a cover layer covering the circuit layer.

According to an embodiment, an RF sensor system comprises a housing including a hole including an area where an RF transmission rod is disposed, and a sensor coupling area provided on the hole, and an RF sensor and an impedance structure selectively coupled to the sensor coupling area.

Additional aspects will be set forth in part in the description which follows and, in part, will be apparent from the description, or may be learned by practice of the presented embodiments.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a perspective view of an RF sensor according to exemplary embodiments.

FIG. 2 is a front view of the RF sensor shown in FIG. 1.

FIG. 3 is a front view of the RF sensor of FIG. 1 for describing an angle between a pair of tangent lines contacting the RF sensor and passing a reference point.

FIG. 4 is a perspective view of an RF sensor system having a measurement mode according to exemplary embodiments.

FIG. 5 is a front view of the RF sensor system shown in FIG. 4.

FIG. 6 is a cross-sectional view of an exposure part for describing a groove, a slot, and a hole.

FIG. 7 is a drawing for explaining a method of coupling a housing and an RF sensor.

FIG. 8 is a perspective view of an RF sensor system in a non-measurement mode according to exemplary embodiments.

FIG. 9 is a perspective view of an impedance structure of the RF sensor system shown in FIG. 8.

FIG. 10 is a drawing for explaining a method of coupling a housing and an impedance structure.

FIG. 11 is a conceptual diagram of a plasma process device according to exemplary embodiments.

FIG. 12 is a conceptual diagram of a plasma process device according to exemplary embodiments.

### DETAILED DESCRIPTION

Hereinafter, example embodiments are described in detail with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, or as “contacting” or “in contact with” another element (or using any form of the word “contact”), there are no intervening elements or layers present.

Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure. It will be also understood that, even if a certain step or operation of manufacturing an apparatus or structure is described later than another step or operation, the step or operation may be performed later than the other step or operation unless the other step or operation is described as being performed after the step or operation.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

As used herein, components described as being “electrically connected” are configured such that an electrical signal can be transferred from one component to the other (although such electrical signal may be attenuated in strength as it is transferred and may be selectively transferred).

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

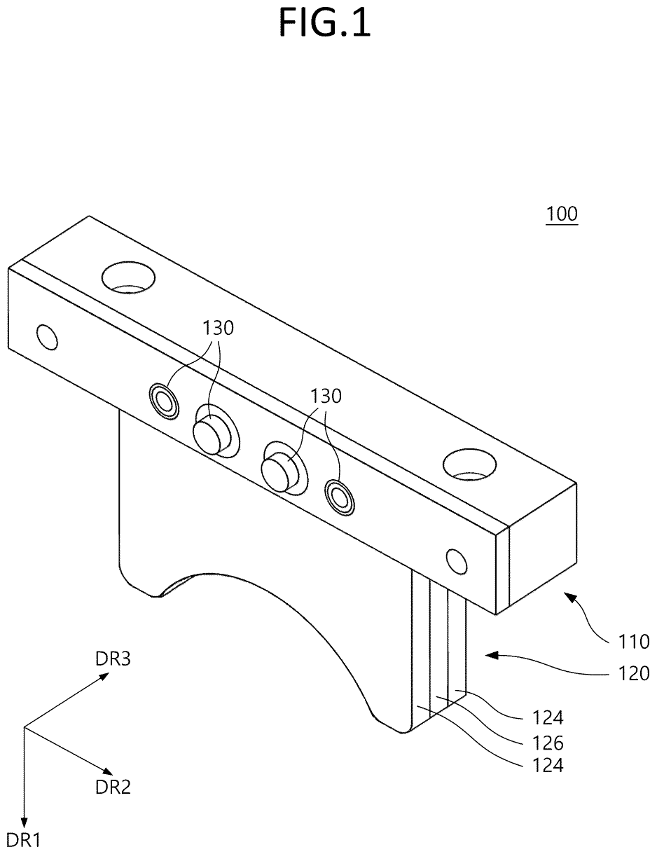

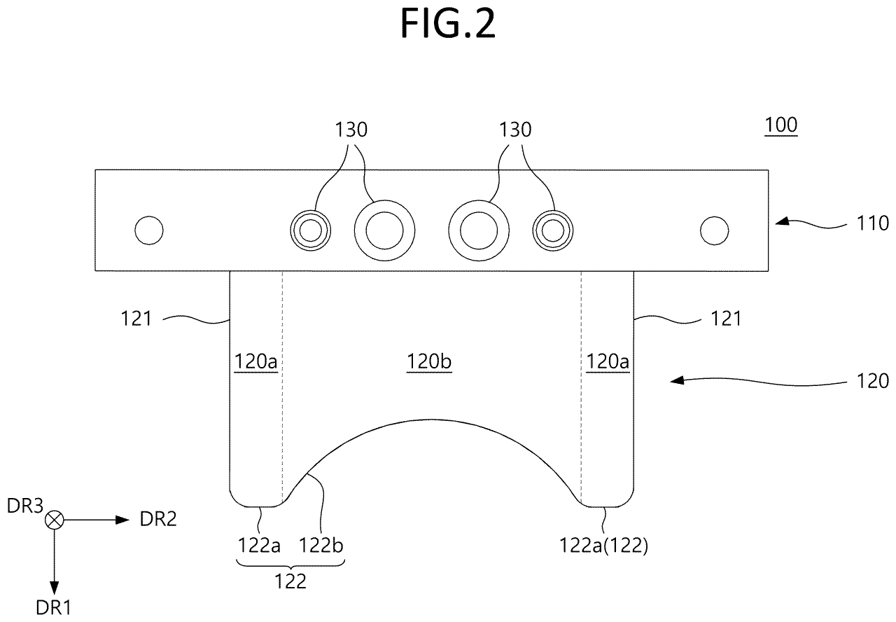

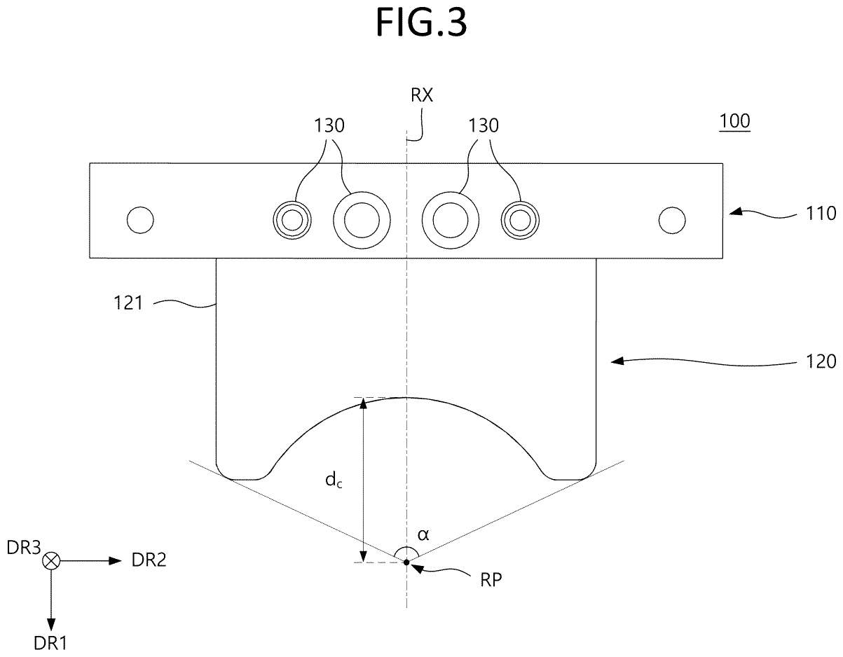

FIG. 1 is a perspective view of an RF sensor according to exemplary embodiments. FIG. 2 is a front view of the RF sensor shown in FIG. 1. FIG. 3 is a front view of the RF sensor of FIG. 1 for describing an angle between a pair of tangent lines contacting the RF sensor and passing a reference point.

Referring to FIGS. 1 to 3, an RF sensor 100 may be provided. The RF sensor 100 may be configured to measure at least one of an RF voltage and an RF current (e.g., an RF signal) transmitted through an RF transmission rod. For example, the RF sensor 100 may be configured to measure the RF current and the RF voltage based on the change in the magnetic field and the intensity of the electric field occurring in the RF transmitted to the RF transmission rod.

The RF sensor 100 may include a fixing part 110, an RF sensing part 120, and signal terminals 130. The fixing part 110 and the RF sensing part 120 may be arranged along a first direction DR1, e.g., a vertical direction. The fixing part 110 and the RF sensing part 120 may have widths along a second direction DR2 crossing the first direction DR1, respectively. The thickness of the fixing part 110 and the RF sensing part 120 may be the size of the RF sensing part 120 along a third direction DR3 crossing the first direction DR1 and the second direction DR2. For example, the first direction DR1, the second direction DR2, and the third direction DR3 may be perpendicular to each other. For example, both of the second and third directions DR2 and DR3 may be horizontal directions.

The width of the fixing part 110 may be greater than the width of the RF sensing part 120. The fixing part 110 may protrude from a pair of sides 121 of the RF sensing part 120 extending along the first direction DR1. One of the pair of sides 121 may be arranged to face the second direction DR2. One end portion of the fixing part 110 may protrude from the one of the pair of sides 121. The other of the pair of sides 121 may be arranged to face a direction opposite to the second direction DR2. The other end portion of the fixing part 110 may protrude from the other of the pair of sides 121. For example, the pair of sides 121 of the RF sensing part 120 may be opposite sides in the second direction DR2. The end portions of the fixing part 110 may be opposite end portions of the fixing part 110 in the second direction DR2, and the end portions of the fixing part 110 may protrude from the opposite sides of the RF sending part 120 outwards in the second direction DR2, respectively.

In exemplary embodiments, the central axis of the fixing part 110 and the central axis of the RF sensing part 120 may be aligned with each other. The central axis of the fixing part 110 may extend along the first direction DR1 and pass through the center of the fixing part 110. The central axis RX of the RF sensing part 120 may extend along the first direction DR1 and pass through the center of the RF sensing part 120. For example, the central axis of the fixing part 110 and the central axis of the RF sensing part 120 extending in the first direction DR1 may overlap each other.

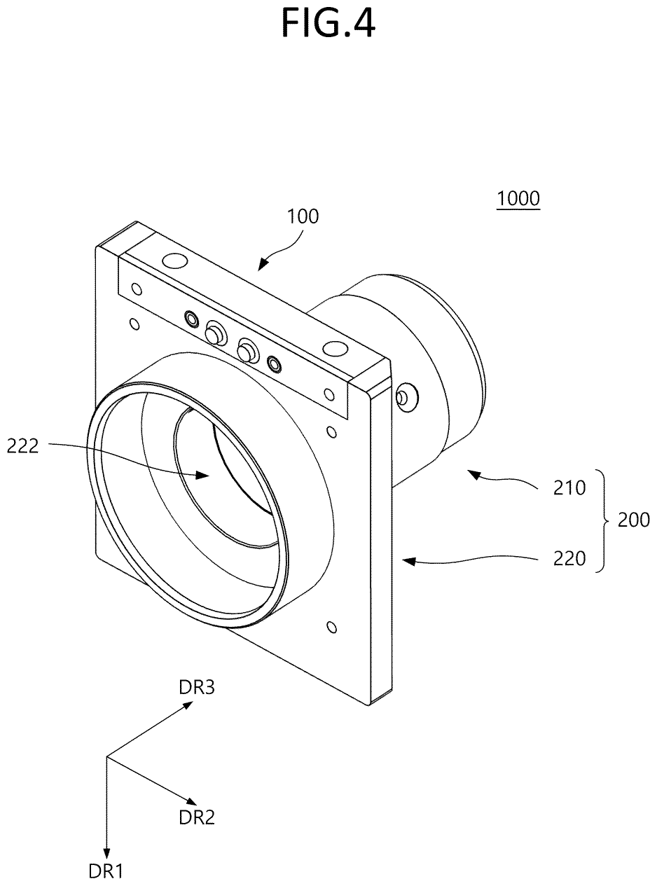

The fixing part 110 may include an electrically conductive material. For example, the fixing part 110 may include aluminum (Al). In exemplary embodiments, the fixing part 110 may be configured to fix the position of the RF sensor 100, e.g., to an RF sensor system 1000 shown in FIGS. 4 to 7. For example, the end portions of the fixing part 110 protruding from both sides 121 of the RF sensing part 120 in the second direction DR2 may be caught or coupled to a structure on which the RF sensor 100 is placed to fix the position of the RF sensor 100, e.g., to an RF sensor system 1000 shown in FIGS. 4 to 7. For example, the fixing part 110 may be fixed to an RF sensor system with screws, latches, hooks, or any other structures/parts which can fix parts together.

The RF sensing part 120 may extend along the first direction DR1. The RF sensing part 120 may include a pair of peripheral sensing areas 120a spaced apart from each other along the second direction DR2 and a central sensing area 120b located between the pair of peripheral sensing areas 120a. The pair of peripheral sensing areas 120a may extend further, e.g., downward, along the first direction DR1 than the central sensing area 120b. The end of the central sensing area 120b located opposite to the fixing part 110 may have a concave shape toward the fixing part 110. For example, the RF sensing part 120 may be fixed to and combined with the fixing part 110.

The RF sensing part 120 may have a bottom surface 122 located opposite to the fixing part 110. The bottom surface 122 may be placed adjacent to the RF transmission rod when the RF sensor 100 measures at least one of the RF voltage and the RF current. For example, the bottom surface 122 may be aligned toward or face the RF transmission rod. The bottom surface 122 may include a central bottom surface 122b and a pair of peripheral bottom surfaces 122a. The central bottom surface 122b may be the bottom surface of the central sensing area 120b. The pair of peripheral bottom surfaces 122a may be the bottom surfaces of the pair of peripheral sensing areas 120a.

The pair of peripheral bottom surfaces 122a may be spaced apart from each other along the second direction DR2 with the central bottom surface 122b therebetween. For example, the pair of peripheral bottom surfaces 122a may extend along the second direction DR2. The central bottom surface 122b may have a concave shape along a direction opposite to the first direction DR1, e.g., upwardly. For example, the central bottom surface 122b may be closer to the fixing part 110 as it gets closer to the central axis of the RF sensing part 120 along the second direction DR2, and may be farther from the fixing part 110 as it gets farther from the central axis of the RF sensing part along the second direction DR2. For example, the central area of the bottom surface of the sensing area 120b may be closer to the fixing part 110 than the peripheral bottom surfaces 122a, and the central area of the central bottom surface 122b may be closer to the fixing part 110 than an edge of the central bottom surfaces 122b. In exemplary embodiments, the central bottom surface 122b may have a constant curvature.

As shown in FIG. 3, an angle α may be defined passing through a reference point RP located on the central axis RX of the RF sensing part 120 and spaced a central distance d_{c} from the RF sensing part 120 along the first direction DR1 and tangential to the RF sensing part 120. The central distance d_{c} may be the reciprocal of the curvature of the central bottom surface 122b. For example, the reference point RP may be a point through which the central axis of the RF transmission rod passes. The central distance d_{c} and the angle α may be determined as needed. For example, the angle α may be 120 degrees (°). For example, the RF sensing part 120 may be designed such that the angle α is 120 degrees (°) when the reference point RP is on a central line or on the central axis RX of the RF sensing part, and the central distance d_{c} from a center of the central bottom surface 122b is the reciprocal of the curvature of the central bottom surface 122b. For example, the sensor coupling area may be in an angular range of 120 degrees along a circumferential direction of the hole from the reference point RP disposed on the central axis RX of the hole.

The RF sensing part 120 may include a circuit required/used for measuring the RF voltage and the RF current. In exemplary embodiments, the RF sensing part 120 may include a pair of cover layers 124 and a circuit layer 126. The pair of cover layers 124 may include an insulating material having mechanical strength and thermal stability. For example, the cover layer may include FR4, FR2, CEM1, CEM3, polytetrafluoroethylene (PTFE), or polyimide. For example, the RF sensing part 120 may be any part including a circuit configured to detect an RF voltage and/or an RF current.

The circuit layer 126 may be provided between the pair of cover layers 124. For example, the circuit layer 126 may include an insulating layer and metal patterns (e.g., copper (Cu) patterns). The metal patterns may form the required/proper circuit for the RF sensor 100 to measure the RF voltage and/or the RF current. Some of the metal patterns may form an inductor. For example, the metal pattern forming the inductor may have a spiral shape. The number of turns, pattern width, and pattern spacing of the metal pattern having a spiral shape may be determined to achieve the required/proper inductance to measure the RF current. A circuit including the inductor may be configured to measure the RF current transmitted through the RF transmission rod. In this specification, a circuit including the inductor may be referred to as an RF current measurement circuit.

Other metal patterns may form a capacitor. In exemplary embodiments, the metal patterns forming the capacitor may be configured to face each other along the thickness direction of the RF sensing part 120, e.g., the third direction DR3. The spacing between the metal patterns forming the capacitor and the width of the metal patterns may be determined to achieve the required/proper capacitance to measure the RF voltage. A circuit including the capacitor may be configured to measure the RF voltage. In this specification, a circuit including the capacitor may be referred to as an RF voltage measurement circuit.

In exemplary embodiments, the RF current measurement circuit and the RF voltage measurement circuit may be electrically separated from each other. In certain exemplary embodiments, the RF current measurement circuit and the RF voltage measurement circuit may be electrically connected to each other. In exemplary embodiments, the circuit layer 126 may extend into the fixing part 110 and overlap with the signal terminals 130 along the third direction DR3.

The signal terminals 130 may penetrate the fixing part 110. One side/end of the signal terminals 130 may be electrically connected to the circuit layer 126, and the other side/end may be exposed to the outside of the fixing part 110. The signal terminals 130 may be provided between a processor outside the RF sensor 100 and the circuit layer 126. The signal terminals 130 may be connected to conductive lines that provide electrical signals to the circuit layer 126 or transmit electrical signals generated in the circuit layer 126 to the processor. For example, the signal terminals 130 may include a low current terminal, a high current terminal, a high voltage terminal, and a low voltage terminal. However, the types of signal terminals 130 may be determined as needed. The processor may be configured to process the electrical signals provided through the signal terminals 130 to obtain at least one of the RF voltage value and the RF current value transmitted through the RF transmission rod.

Unlike the RF sensor 100 of the present disclosure, when an RF sensor has a structure including a hole through which the RF transmission rod passes, the RF transmission rod need to be separated from other devices (e.g., lower impedance matcher, RF load) each time the RF sensor is installed to measure RF characteristics (e.g., RF voltage and RF current). For example, a worker installing the RF sensor need to separate the RF transmission rod and the lower impedance matcher, insert the RF transmission rod into the hole of the RF sensor, and then re-couple the lower impedance matcher and the RF transmission rod. Accordingly, resources such as manpower, time, and cost may be excessively consumed for device setup to measure at least one of the RF voltage and the RF current.

The RF sensor 100 of the present disclosure may be configured to measure at least one of the RF voltage and the RF current by being placed adjacent to one side of the RF transmission rod. The RF sensor 100 may not require a change in the assembly state of the RF transmission rod and other devices. Therefore, resources such as manpower, time, and cost used for device setup when measuring at least one of the RF voltage and the RF current may be saved and consumed relatively less.

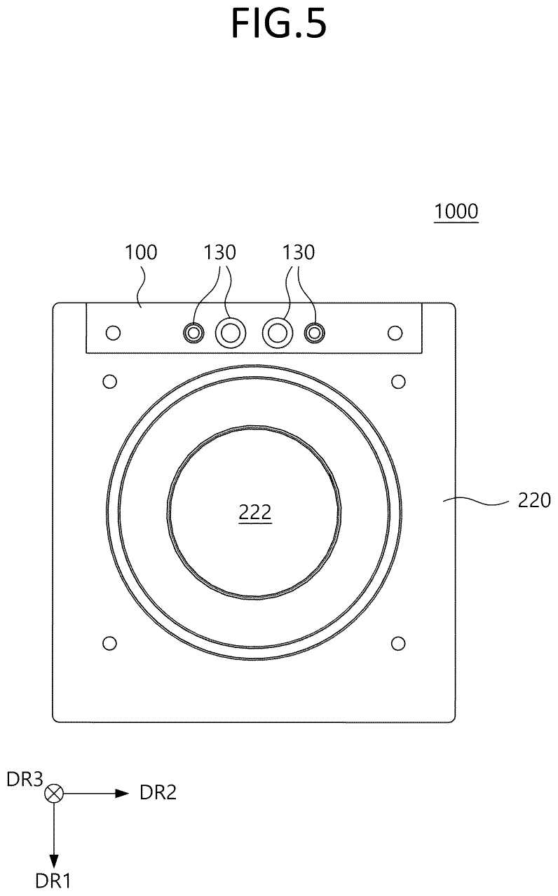

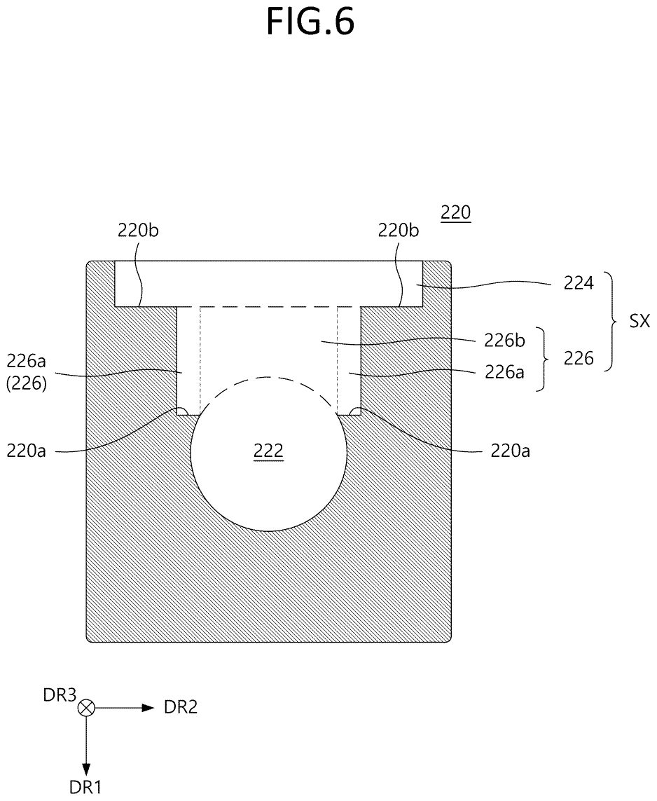

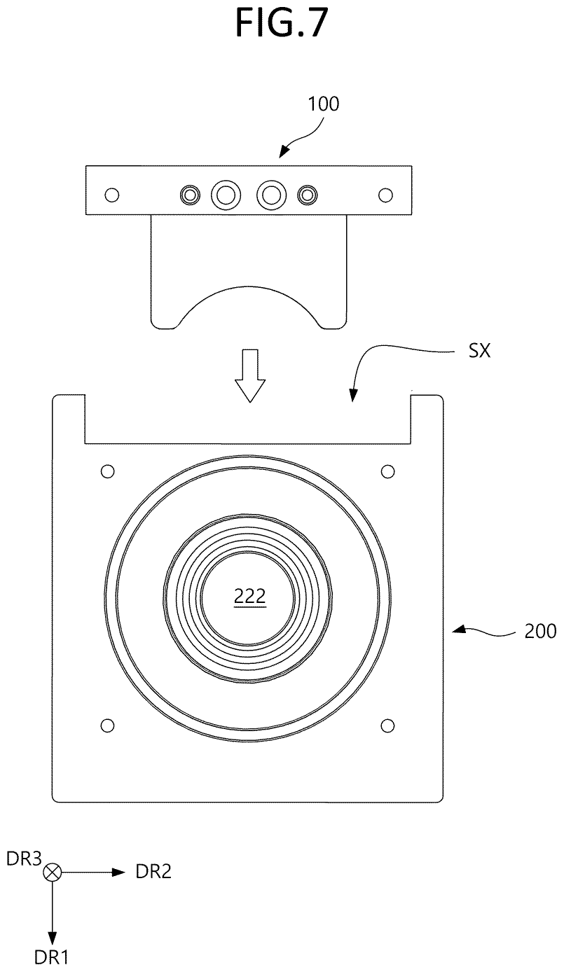

FIG. 4 is a perspective view of an RF sensor system having a measurement mode according to exemplary embodiments. FIG. 5 is a front view of the RF sensor system shown in FIG. 4. FIG. 6 is a cross-section of an exposure part of an RF sensor system for describing a groove, a slot, and a hole. FIG. 7 is a drawing for explaining a method of coupling a housing and an RF sensor. For conciseness of explanation, the same contents as described with reference to FIGS. 1 to 3 may not be described below. Therefore, the description with respect to FIGS. 1 to 3 may also be applied to the present embodiment unless the context indicates otherwise.

Referring to FIGS. 4 to 7, an RF sensor system 1000 having a measurement mode may be provided. The RF sensor system 1000 having a measurement mode may include a housing 200 and an RF sensor 100. In the measurement mode, the RF sensor system 1000 may be configured to measure RF characteristics transmitted through an RF transmission rod. The RF sensor 100 may be substantially the same as the RF sensor 100 described with reference to FIGS. 1 to 3. The first direction DR1, the second direction DR2, and the third direction DR3 shown in FIGS. 4 to 7 may be the same as the first direction DR1, the second direction DR2, and the third direction DR3, respectively, when the RF sensor 100 is coupled to the housing 200.

The housing 200 may include a device coupling part 210 and an exposure part 220. The device coupling part 210 and the exposure part 220 may be connected to each other along the third direction DR3. One side/end of the device coupling part 210 may be configured to be coupled to a device using RF power (e.g., a plasma process device). The other side/end of the device coupling part 210 may be configured to be coupled to the exposure part 220. The coupling method may be determined as needed. The device coupling part 210 may define an area where the RF transmission rod is inserted. For example, the device coupling part 210 may have a tube shape extending along the third direction DR3. The device coupling part 210 and the RF transmission rod inserted into the device coupling part 210 may extend substantially in the same direction. The device coupling part 210 may include an electrically conductive material. For example, the device coupling part 210 may include aluminum (Al).

The exposure part 220 may be exposed to the outside of the device using RF power. The exposure part 220 may have a plate shape. The exposure part 220 may include a hole 222 into which the RF transmission rod is inserted and a sensor coupling area SX to which the RF sensor 100 is coupled. The sensor coupling area SX may include a groove 224 (e.g., a recess formed on the exposure part 220) into which the fixing part 110 is inserted and a slot 226 into which the RF sensing part 120 is inserted.

The hole 222 may be connected to the area in the device coupling part 210 where the RF transmission rod is inserted. For example, the RF transmission rod may be inserted into the housing 200 through the hole 222 and extend to the device using RF power through the device coupling part 210. The RF transmission rod may be located in the center of the hole 222. For example, the central axis of the RF transmission rod may be aligned with and/or overlap the central axis of the hole 222. The central axis of the hole 222 may pass through the center of the hole 222 and extend along the third direction DR3. In exemplary embodiments, the hole 222 may have a circular shape, e.g., a circular cross-section. The radius of the hole 222 may be greater than the radius of the RF transmission rod. Accordingly, a surface (e.g., an inner surface) of the exposure part 220 exposed by the hole 222, e.g., the sidewall of the hole 222, may be spaced apart from the RF transmission rod.

As shown in FIG. 6, the groove 224 and the slot 226 may be formed on one side of the hole 222. The groove 224, the slot 226, and the hole 222 may be arranged along the first direction DR1. When the housing 200 is installed in the device using RF power, the first direction DR1 may be the gravity direction. When the housing 200 is installed in the device using RF power, the groove 224 and the slot 226 may be provided at a higher position than the hole 222.

The slot 226 may extend along the first direction DR1. The slot 226 may be connected to the hole 222. The slot 226 may include a pair of peripheral slot areas 226a spaced apart from each other along the second direction DR2 and a central slot area 226b provided between the pair of peripheral slot areas 226a. The pair of peripheral slot areas 226a may extend further along the first direction DR1 than the central portion of the central slot area 226b. The maximum size of the pair of peripheral slot areas 226a along the first direction DR1 may be greater than the minimum size of the central slot area 226b along the first direction DR1.

The pair of peripheral slot areas 226a may expose two first upper surfaces 220a of the housing 200. For example, the pair of peripheral slot areas 226a may expose two first upper surfaces 220a of the housing 200. The two first upper surfaces 220a may be spaced apart from each other along the second direction DR2. The first upper surfaces 220a may face the direction opposite to the first direction DR1. For example, the first upper surfaces 220a may face upward. In exemplary embodiments, the first upper surfaces 220a may contact the RF sensing part 120. The central slot area 226b may be connected to the hole 222 along the first direction DR1. The end of the central slot area 226b connected to the hole 222 may have a shape corresponding to the hole 222. For example, the end of the central slot area 226b adjacent to the hole 222 may be concave.

The slot 226 may have a shape corresponding to the RF sensing part 120. For example, the slot 226 may have substantially the same shape as the RF sensing part 120. When the RF sensing part 120 is inserted into the slot 226, the central bottom surface 122b of the RF sensing part 120 may be exposed to the hole 222. The curvature of the hole 222 may be substantially the same as the curvature of the central bottom surface 122b. A part of the hole 222 may be defined by the housing 200, and another part of the hole 222 may be defined by the RF sensing part 120, e.g., when the RF sensing part 120 is inserted in the slot 226.

The groove 224 may be provided on the slot 226. The groove 224 and the slot 226 may be arranged along the first direction DR1. The groove 224 and the slot 226 may be connected to each other. The width of the groove 224 may be greater than the width of the slot 226. The width of the groove 224 and the width of the slot 226 may be the sizes of the groove 224 and the slot 226 along the second direction DR2, respectively. In exemplary embodiments, the central axis of the groove 224 and the central axis of the slot 226 may be aligned with and/or overlap each other. The central axis of the groove 224 and the central axis of the slot 226 may pass through the center of the groove 224 and the center of the slot 226, respectively, and extend along the first direction DR1.

The groove 224 may expose second upper surfaces 220b of the housing 200. For example, the groove 224 may expose two second upper surfaces 220b of the housing 200. The two second upper surfaces 220b may be spaced apart from each other along the second direction DR2. The second upper surfaces 220b may face the direction opposite to the first direction DR1. For example, the second upper surfaces 220b may face upward. When the RF sensor 100 is installed in the housing 200, the fixing part 110 may be inserted into the groove 224. For example, the fixing part 110 may contact the second upper surfaces 220b.

The housing 200 may constitute a coaxial RF path with the RF transmission rod. The housing 200 may be a ground structure in the coaxial RF path. For example, the housing 200 may be used as a ground.

The RF sensor 100 may be coupled to the housing 200. The RF sensing part 120 may be inserted into the slot 226 and the fixing part 110 may be inserted into the groove 224. The fixing part 110 may be configured to be caught/fixed by the housing 200 to fix the position of the RF sensor 100 relative to the housing 200. In exemplary embodiments, the fixing part 110 may be screw-coupled to the exposure part 220.

The RF sensing part 120 may be configured to measure at least one of the RF voltage and the RF current transmitted through the RF transmission rod passing through the interior of the device coupling part 210 and the hole 222 of the exposure part 220 and to generate an electrical signal. For example, the electrical signal may be generated by the RF voltage and/or the RF current transmitted through the RF transmission rod. The electrical signal may be delivered to a processor through the signal terminals 130. The processor may be configured to process the electrical signals provided through the signal terminals 130 to obtain at least one of the RF voltage value and the RF current value transmitted through the RF transmission rod.

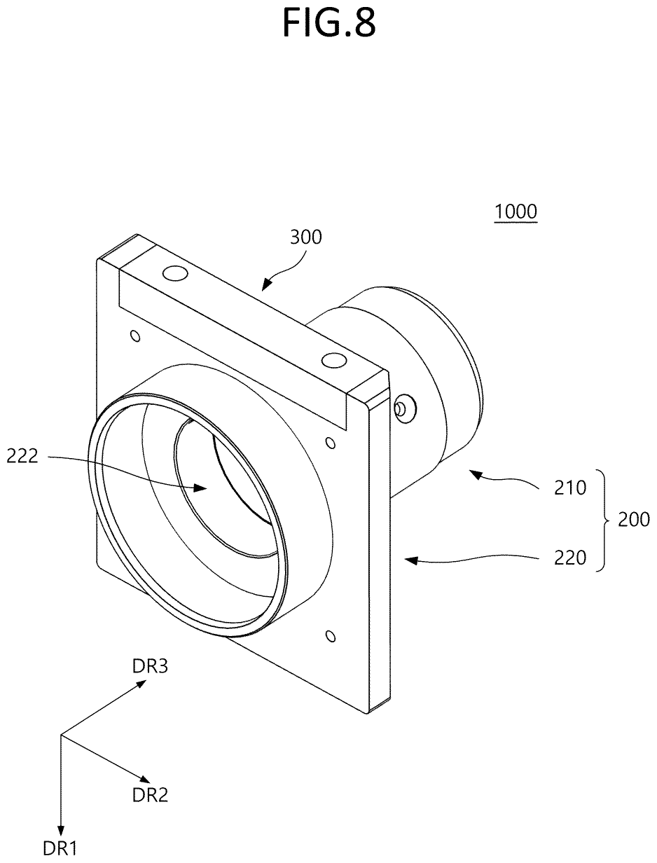

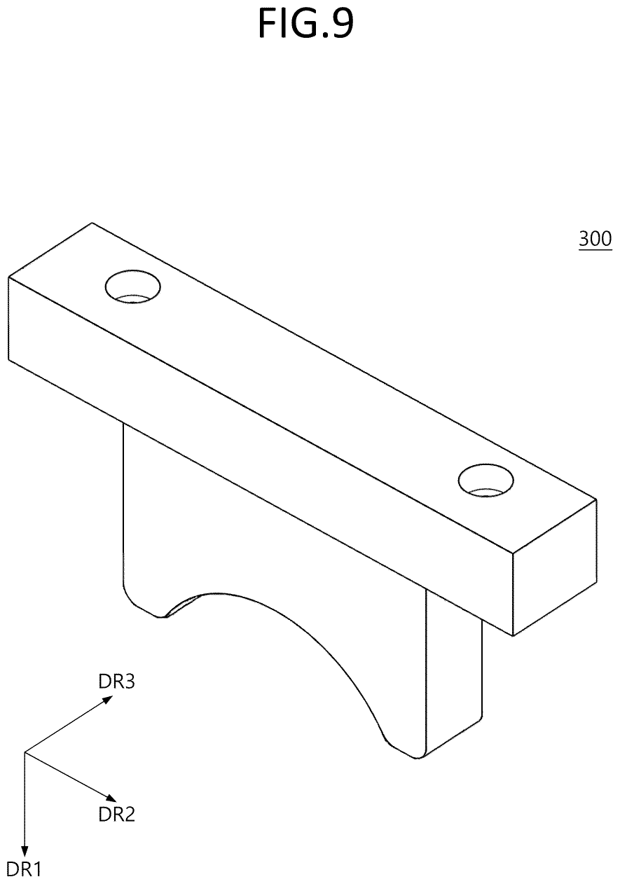

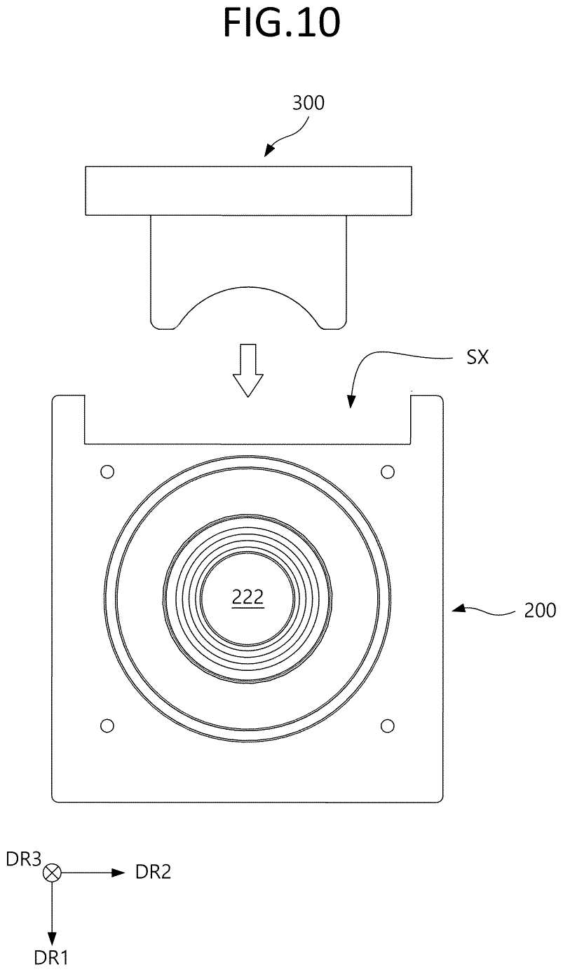

FIG. 8 is a perspective view of an RF sensor system having a non-measurement mode according to exemplary embodiments. FIG. 9 is a perspective view of an impedance structure 300 of the RF sensor system shown in FIG. 8. FIG. 10 is a drawing for explaining a method of coupling a housing and an impedance structure. For conciseness of explanation, the same contents as described with reference to FIGS. 1 to 3 and the same contents as described with reference to FIGS. 4 to 7 may not be described below. Therefore, the descriptions with respect to FIGS. 1 to 7 may also be applied to the present embodiment unless the context indicates otherwise.

Referring to FIGS. 8 to 10, an RF sensor system 1000 having a non-measurement mode may be provided. In the non-measurement mode, the RF sensor system 1000 may be configured not to measure RF characteristics transmitted through an RF transmission rod. The RF sensor system 1000 having a non-measurement mode may include a housing 200 and an impedance structure 300. The housing 200 may be substantially the same as the housing 200 described with reference to FIGS. 4 to 7.

The impedance structure 300 may be coupled to the housing 200 instead of the RF sensor 100. The impedance structure 300 and the RF sensor 100 may be selectively coupled to the housing 200. The impedance structure 300 may be inserted into the groove 224 and the slot 226. The shape and material of the impedance structure 300 may be determined so that the RF path including the RF transmission rod has the required/proper characteristic impedance. In exemplary embodiments, the impedance structure 300 may have substantially the same shape and the same size as the RF sensor 100. In exemplary embodiments, the impedance structure 300 may include substantially the same material as the housing 200. For example, the impedance structure 300 may include aluminum (Al).

A coaxial RF path may consist of an inner cable and an outer cable that share an axis. For the coaxial RF path, the characteristic impedance of the RF path may be determined by the outer diameter of the inner cable (For example, RF transmission rod), the inner diameter of the outer cable (for example, housing 200), and the dielectric constant of the dielectric between the outer cable and the inner cable. When not measuring RF characteristics, the inner cable may be completely surrounded by the outer cable along the circumferential direction. When the inner cable is completely surrounded by the outer cable along the circumferential direction, the characteristic impedance of the RF path may be referred to as a reference characteristic impedance.

To measure RF characteristics, a portion of the outer cable may be replaced with an RF sensor. Replacing a portion of the outer cable with an RF sensor changes the outer diameter of the outer cable, so the characteristic impedance of the RF path may be changed to be different from the reference characteristic impedance. When the RF sensor has a structure that completely surrounds the RF transmission rod along its circumferential direction, the difference between the reference characteristic impedance and the changed characteristic impedance may be relatively large.

The RF sensor 100 of the present disclosure may be placed only on one side of the RF transmission rod without completely surrounding the RF transmission rod along its circumferential direction. Accordingly, the RF sensor 100 may cause less change in the characteristic impedance of the RF path than an RF sensor that completely surrounds the RF transmission rod.

When an RF sensor has a structure that surrounds all around the circumference of the RF transmission rod, the RF transmission rod needs to be separated from other devices (e.g., lower impedance matcher, device using RF power) each time the RF sensor is installed to measure RF characteristics. Resources such as manpower, time, and cost may be wasted for device setup to measure the RF voltage and/or the RF current.

The RF sensor system 1000 of the present disclosure can measure the RF voltage and/or RF current delivered to the RF transmission rod by inserting the RF sensor 100 into the housing 200 while the housing 200 is assembled to the device using RF power. Disassembling and reassembling the RF transmission rod from the other devices may not be required to measure RF characteristics. Accordingly, resources such as manpower, time, and cost used for device setup may be saved and consumed relatively less.

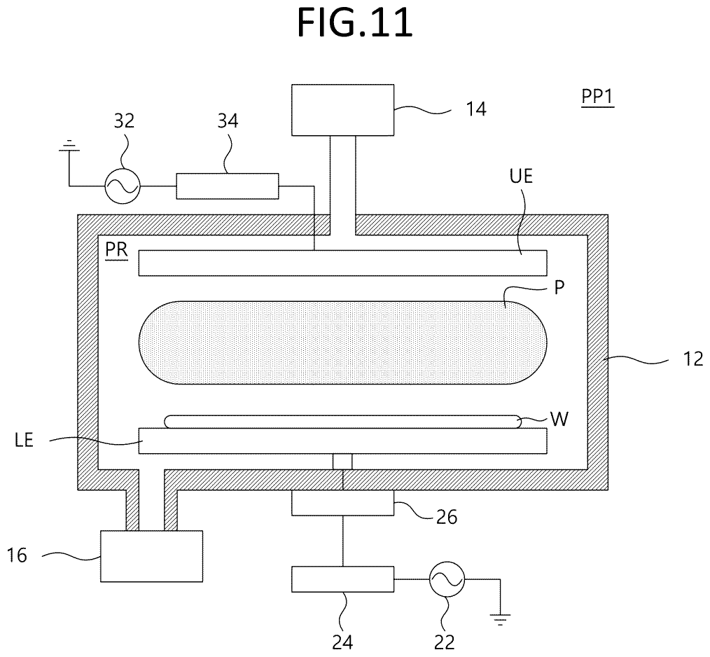

FIG. 11 is a conceptual diagram of a plasma process device according to exemplary embodiments. For conciseness of explanation, descriptions of the same contents as described above may be omitted in the below description. Therefore, the descriptions with respect to above embodiments may also be applied to the present embodiment unless the context indicates otherwise.

Referring to FIG. 11, a plasma process device PP1 may be provided. For example, the plasma process device PP1 may be a plasma etching device, a plasma deposition device, or a plasma surface treatment device. Hereinafter, a plasma etching device is described as an example. The plasma process device PP1 may include a process chamber 12, a process gas supply part 14, an exhaust part 16, a lower RF power source 22, a lower impedance matcher 24, a lower RF sensor system 26, an upper RF power source 32, and an upper impedance matcher 34.

The process chamber 12 may define a process area PR where plasma P is generated from the process gas introduced by the process gas supply part 14. The process area PR may be an internal area of the process chamber 12. For example, the process gas may include O₂, Cl₂, and SF₆. The plasma P generated in the internal space of the process chamber 12 may be used to perform a plasma etching process on a substrate W that is a target to be processed.

The process chamber 12 may include a material with excellent wear resistance and corrosion resistance. For example, the process chamber 12 may include an aluminum (Al) series metal, an oxide or nitride of an aluminum (Al) series metal, a stainless steel (SUS) series metal, a nitride or oxide of a stainless steel (SUS) series metal, and alloys or combinations thereof. The process chamber 12 may maintain the internal space in a sealed state with the required/proper pressure and required/proper temperature in the plasma etching process.

The process chamber 12 may include a lower electrode LE and an upper electrode UE. The lower electrode LE and the upper electrode UE may be located at the bottom and top of the internal space of the process chamber 12, respectively. The lower electrode LE and the upper electrode UE may face each other.

The lower electrode LE may be configured to support the substrate W. For example, the lower electrode LE may be an electrostatic chuck (ESC) that fixes the substrate W using electrostatic force. Ions and/or reactive gases of the plasma P may be provided to the substrate W to perform the plasma etching process. In exemplary embodiments, a heater may be provided inside the lower electrode LE to heat the substrate W to improve etching characteristics.

The lower RF power source 22 may be configured to apply RF power to the lower electrode LE. For example, the RF power applied to the lower electrode LE may be a bias voltage for adjusting the ion energy (or Ion Bombardment Energy) of the process gas excited to a plasma state to proceed with etching. The lower impedance matcher 24 may be configured to match the characteristic impedance of the RF path connected to the lower electrode LE to the impedance of the lower electrode LE.

The lower RF sensor system 26 may be substantially the same as the RF sensor system 1000 described with reference to FIGS. 4 to 10. The lower RF sensor system 26 may be provided on the RF path between the lower impedance matcher 24 and the process chamber 12. The RF sensor system 26 may be configured to measure the RF voltage and RF current supplied to the lower electrode LE. As described with reference to FIGS. 4 to 10, the device coupling part 210 may be coupled to the process chamber 12.

The upper electrode UE may be electrically connected to the upper RF power source 32 through the upper impedance matcher 34. The upper RF power source 32 may be configured to supply RF power to the upper electrode UE. The upper impedance matcher 34 may be configured to match the characteristic impedance of the RF path connected to the upper electrode UE to the impedance of the upper electrode UE. For example, the RF power applied to the upper electrode UE may be determined to generate plasma in the process chamber 12. The structure of the upper electrode UE may be determined as needed. For example, the upper electrode UE may include a shower head type electrode including a plurality of gas injection holes, a flat plate type electrode having a planar structure, a spiral coil electrode, or a combination thereof.

An exhaust part 16 may be connected to the process chamber 12 to discharge gas from the internal space of the process chamber 12. For example, the exhaust part 16 may be connected to the bottom of the process chamber 12. In exemplary embodiments, the exhaust part 16 may include an exhaust device. For example, the exhaust device may include or may be a vacuum pump.

The lower RF sensor system 26 of the present disclosure measures RF characteristics by inserting the RF sensor 100 into the slot 226 of the housing 200, so resources such as manpower, time, and cost required/used for device setup when measuring at least one of the RF voltage and the RF current may be saved and consumed relatively less. Furthermore, since the RF sensor 100 is provided only on a portion of the RF transmission rod, the change in the characteristic impedance of the RF path may be minimized.

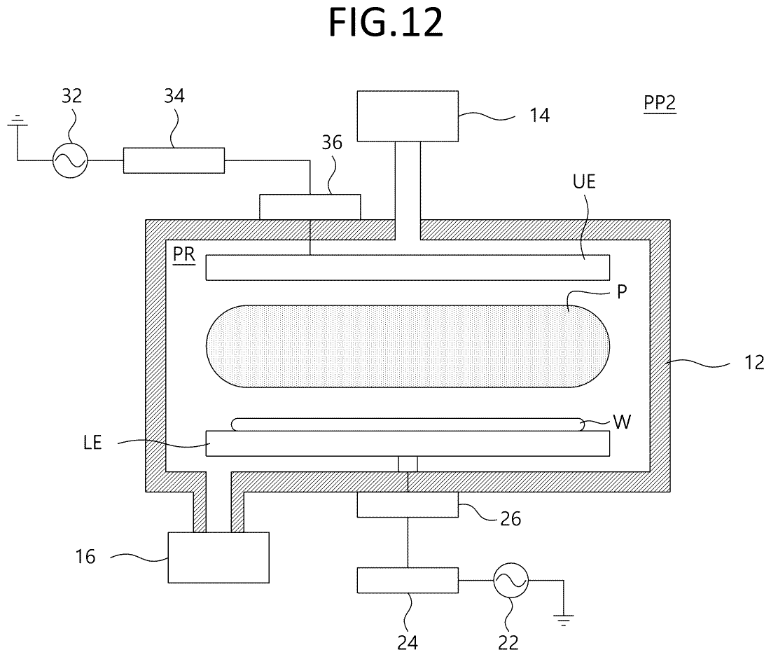

FIG. 12 is a conceptual diagram of a plasma process device according to exemplary embodiments. For conciseness of explanation, description of the same contents as described with reference to FIG. 11 may be omitted in the present embodiment. Therefore, the description with respect to FIG. 12 may also be applied to the present embodiment unless the context indicates otherwise.

Referring to FIG. 12, a plasma process device PP2 may be provided. Unlike that described with reference to FIG. 11, the plasma process device PP2 may further include an upper RF sensor system 36 on the RF path between the upper impedance matcher 34 and the process chamber PP2. The upper RF sensor system 36 may be substantially the same as the RF sensor system 1000 described with reference to FIGS. 4 to 10. The upper RF sensor system 36 may be configured to measure the RF voltage and RF current supplied to the upper electrode UE. As described with reference to FIGS. 4 to 10, the device coupling part 210 may be coupled to the process chamber PP2.

In other exemplary embodiments, the plasma process device PP2 may include the upper RF sensor system 36 without the lower RF sensor system 26.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

According to the present disclosure, an RF sensor system with a small change in the characteristic impedance of the RF path when measuring RF characteristics may be provided.

According to the present disclosure, an RF sensor system in which resources required/used for device setup for RF characteristic measurement are saved and reduced may be provided.

While the present disclosure has been described with reference to embodiments thereof, it will be apparent to those of ordinary skill in the art that various changes and modifications may be made thereto without departing from the spirit and scope of the present invention as set forth in the following claims.

What is claimed is:

1. An RF sensor system having first and second modes, comprising:
a housing; and
an RF sensor coupled to the housing in the first mode,
wherein the housing includes, a hole including an area where an RF transmission rod is disposed, and a sensor coupling area configured for the RF sensor to be coupled.

2. The RF sensor system of claim 1, wherein the sensor coupling area includes, a slot on the hole, and a groove on the slot and having a width greater than the slot.

3. The RF sensor system of claim 2, wherein the RF sensor includes, an RF sensing part inserted into the slot, and a fixing part inserted into the groove.

4. The RF sensor system of claim 3, wherein the fixing part protrudes in a horizontal direction from both sides of the RF sensing part.

5. The RF sensor system of claim 3,
wherein the RF sensing part includes, a pair of peripheral sensing areas spaced apart from each other along a second direction crossing a first direction, and a central sensing area between the pair of peripheral sensing areas, and
wherein the pair of peripheral sensing areas extends further along the first direction than the central sensing area.

6. The RF sensor system of claim 5,
wherein the central sensing area includes a bottom surface having a concave shape, and
wherein the hole exposes an inner surface of the housing and the bottom surface of the central sensing area having the concave shape.

7. The RF sensor system of claim 6, wherein a curvature of the bottom surface of the central sensing area is the same as a curvature of the hole.

8. The RF sensor system of claim 5, wherein the pair of peripheral sensing areas face the housing along the first direction, and
wherein the central sensing area faces the hole along the first direction.

9. The RF sensor system of claim 3, wherein the RF sensing part includes at least one of an RF voltage measurement circuit and an RF current measurement circuit.

10. The RF sensor system of claim 9,
wherein the RF sensing part includes, a circuit layer including metal patterns, and a cover layer covering the circuit layer, and
wherein the RF voltage measurement circuit and the RF current measurement circuit include a capacitor and an inductor, respectively, formed by the metal patterns.

11. The RF sensor system of claim 2, wherein the hole, the slot, and the groove are connected.

12. The RF sensor system of claim 2,
wherein the slot includes, a pair of peripheral slot areas spaced apart from each other along a second direction crossing a first direction, and a central slot area between the pair of peripheral slot areas, and
wherein the pair of peripheral slot areas extends further along the first direction than the central slot area.

13. The RF sensor system of claim 12, wherein a width of the groove along the second direction is greater than a width of the slot along the second direction.

14. The RF sensor system of claim 1, wherein the housing includes, an exposure part including the hole and the sensor coupling area, and a device coupling part configured to be coupled to a device outside the housing.

15. The RF sensor system of claim 14, wherein the device coupling part has a tube shape connected to the hole.

16. The RF sensor system of claim 1, wherein the sensor coupling area is in an angular range of 120 degrees along a circumferential direction of the hole from a point on a central axis of the hole.

17. The RF sensor system of claim 1,
wherein the RF transmission rod is configured to be applied with an RF signal, and
wherein the housing is used as a ground.

18. The RF sensor system of claim 1, further comprising:
an impedance structure coupled to the housing instead of the RF sensor in the second mode,
wherein the impedance structure is coupled to the sensor coupling area.

19. An RF sensor system comprising:
a housing; and
an RF sensor coupled to the housing,
wherein the housing includes, a hole including an area where an RF transmission rod is disposed, and a slot on the hole, and
wherein the RF sensor is inserted into the slot and includes a circuit layer including metal patterns and a cover layer covering the circuit layer.

20. An RF sensor system comprising:
a housing including a hole including an area where an RF transmission rod is disposed; and a sensor coupling area provided on the hole; and
an RF sensor and an impedance structure selectively coupled to the sensor coupling area.
